(19) United States
(12) Patent Application Publication
(10) Pub. No.: US 2014/0174364 A1
(43) Pub. Date: Jun. 26, 2014

(54) HEAT TREATMENT DEVICE

(71) Applicants: Ken Nakao, Yamanashi (JP); Eisuke Morisaki, Yamanashi (JP)

(72) Inventors: Ken Nakao, Yamanashi (JP); Eisuke Morisaki, Yamanashi (JP)

(73) Assignee: TOKYO ELECTRON LIMITED, Tokyo (JP)

(21) Appl. No.: 14/236,955

(22) PCT Filed: Jul. 23, 2012
(86) PCT No.: PCT/JP2012/068616

§ 371 Date: Feb. 4, 2014

(30) Foreign Application Priority Data
Sep. 2, 2011 (JP) 2011-101900

(51) Int. Cl. C23C 16/46

(52) U.S. Cl. CPC C23C 16/46
USPC 118/725

(57) ABSTRACT

A heat treatment device includes: a processing container that accommodates a plurality of substrates to be subjected to heat treatment; a substrate holding member that holds the plurality of substrates; an induction heating coil that forms an induction magnetic field inside the processing container; a high frequency power supply that applies a high frequency electric power to the induction heating coil; a gas supply mechanism that supplies a processing gas to the inside of the processing container; an exhaust mechanism that exhausts the inside of the processing container; and an induction heating element provided between the induction heating coil and the substrate holding member to enclose the substrate holding member inside the treatment container. The induction heating element is heated by an induction electric current formed by the induction magnetic field, and the substrates are heated by radiation heat from the induction heating element. The flow of the inductive electric current to the substrate is blocked by the induction heating element.

### TECHNICAL FIELD

The present disclosure relates to a heat treatment device that performs a heat treatment on a substrate using induction heating.

### BACKGROUND

When a heat treatment such as a film forming or an oxidation processing is performed on a substrate such as, for example, a semiconductor wafer, a batch type heat treatment is widely used in which a plurality of substrates are disposed within a processing container made of quartz and heated by a resistance heating type heater or a heating lamp.

Recently, it has been reviewed to form a film of a compound such as, for example, SiC or GaN in a batch type heat treatment device. When forming such a compound film, it is required to heat a substrate to a high temperature that exceeds 1,000° C. However, a heat treatment device using the resistance heating type heater or the heating lamp to heat a substrate is limited in that its heating temperature is about 1,000° C., and has difficulty in coping with an application of forming such a compound film.

What is known as a technique that enables heating to a high temperature in excess of 1,000° C. is to arrange a high frequency induction heating coil outside a container and inductively heat a plurality of substrate held on a susceptor installed inside the container (see, e.g., FIG. 4 of Patent Document 1).

### PRIOR ART DOCUMENT

### Patent Document

Patent Document 1: Japanese Patent Laid-Open Publication No. H5-21359

### SUMMARY OF THE INVENTION

However, when the substrates are heated using such induction heating, an induction current also flows in the substrates, exerting a bad influence. For example, uniformity in processing may deteriorate.

Accordingly, an object of the present disclosure is to provide a heat treatment device using induction heating in which an influence of an induction current on a substrate may be excluded so as to perform a heat treatment uniformly.

The present disclosure provides a heat treatment device that performs a heat treatment on a plurality of substrates. The heat treatment device includes: a processing container configured to accommodate a plurality of substrates to be subjected to a heat treatment; a substrate holding member configured to hold the plurality of substrates inside the processing container; an induction heating coil configured to form an induction magnetic field inside the processing so as to perform induction heating; a high frequency power supply configured to apply a high frequency power to the induction heating coil; a gas supply mechanism configured to supply one or more processing gases to the inside of the processing container; an exhaust mechanism configured to exhaust the inside of the processing container; and an induction heating element provided between the induction heating coil and the substrate holding member so as to enclose the substrate holding member inside the processing container. The induction heating element is heated by an induction electric current formed by the induction magnetic field and the plurality of substrates held by the substrate holding element is heated by radiation heat from the induction heating element. The flow of the induction electric current to the plurality of substrates is blocked by the induction heating element.

In the present disclosure, at least one of the thickness of the induction heating element, the frequency of the high frequency power, and the distance between the induction heating coil and the plurality of substrates may be adjusted in such a manner that the flow of the induction current to the plurality of substrates may be blocked.

In the present disclosure, the processing container is made of a dielectric material and the induction heating coil may b wound on an outer circumference of the processing container. In addition, the substrate holding member forms a polygonal column extending vertically in the processing container, and the plurality of substrates may be held on side surfaces of the substrate holding member. Further, the induction heating element is preferably made of graphite.

In the present disclosure, the gas supply mechanism may include a shower head configured to introduce the processing gases into the processing container in a form of shower. In addition, the heat treatment device may further include a rotation mechanism configured to rotate the substrate holding member. Further, as for the heat treatment, a film-forming processing that forms a prescribed film by reacting the processing gases on the plurality of substrates may be exemplified. As for the film forming, a film forming of a silicon carbide (SiC) film or a gallium nitride (GaN) film may be exemplified.

In the present disclosure, the heat treatment forms a compound film using a plurality of processing gases and the heat treatment device further includes a rotation mechanism configured to rotate the substrate holding member. The gas supply mechanism may supply each of the plurality of processing gases to one of different regions in the processing container, and the substrate holding member may be rotated by the rotation mechanism so that the plurality of substrates may sequentially pass through each of the regions, thereby causing the plurality of processing gases to be sequentially adsorbed onto the plurality of substrates. In this case, the gas supply mechanism may include a plurality of shower heads that are configured to introduce the plurality of processing gases to the different regions in the processing container, respectively. In addition, it may be exemplified that the compound film is a SiC film, and a Si source gas, a C source gas and a reducing gas are used as the plurality of gases.

### BRIEF DESCRIPTION OF THE DRAWINGS

FIG. 1 is a cross-sectional view illustrating a heat treatment device according to a first exemplary embodiment of the present disclosure.

FIG. 2 is a schematic view illustrating an example of a barrel type susceptor for use in the heat treatment device of FIG. 1.

FIG. 3 is a schematic view illustrating another example of a barrel type susceptor for use in the heat treatment device of FIG. 1.

FIG. 4 is a cross-sectional view illustrating a main portion of the heat treatment device of FIG. 1 in which a shower head configured to introduce a processing gas into a processing container is provided in the heat treatment device.

FIG. 5 is a cross-sectional view illustrating the heat treatment device of FIG. 1 in which three zones are provided in the height direction of the processing container such that separate coils are installed at the zones, respectively, and the high frequency power of each of the zones is controlled.

FIG. 6 is a cross-sectional view illustrating a heat treatment device according to a second exemplary embodiment of the present disclosure.

FIG. 7 is a schematic view illustrating a concept when a SiC film is formed using the heat treatment device according to the second exemplary embodiment of the present disclosure.

FIG. 8 is a schematic view illustrating another example of a susceptor.

FIG. 9 is a schematic view illustrating another example of a susceptor.

### DETAILED DESCRIPTION TO EXECUTE THE INVENTION

Hereinafter, exemplary embodiments of the present disclosure will be described with reference to the accompanying drawings.

### First Exemplary Embodiment

At first, description will be made on a first exemplary embodiment.

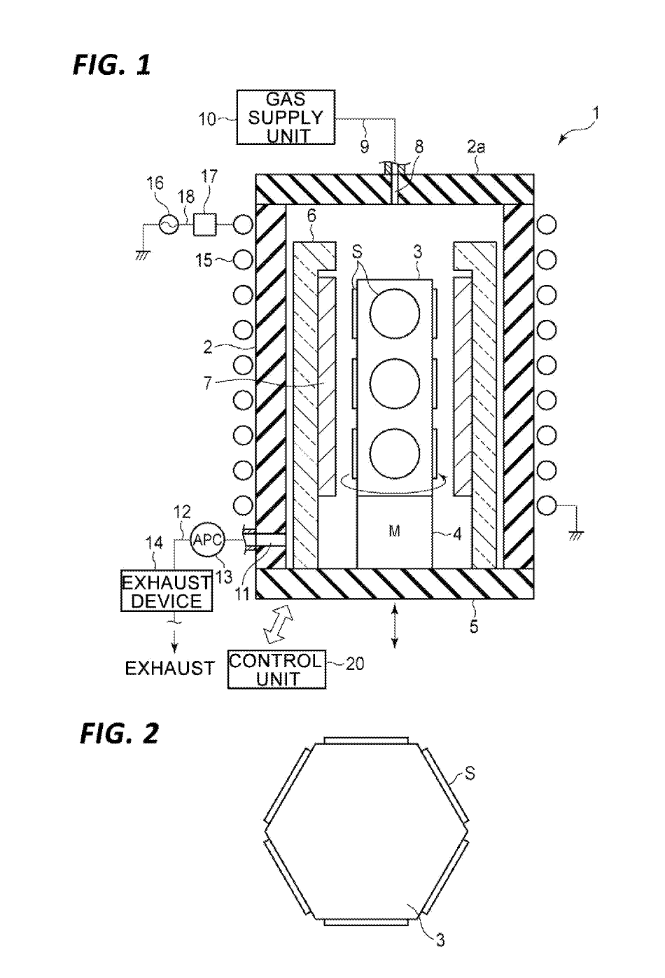

FIG. 1 is a cross-sectional view illustrating a heat treatment device according to the first exemplary embodiment of the present disclosure. As illustrated in FIG. 1, the heat treatment device 1 includes a vertical processing container formed in a cylindrical shape that extends in the vertical direction. The processing container 2 includes a ceiling wall 2a that closes the top end of the processing container 2. The bottom end of the processing container 2 is opened. The processing container 2 is made of a dielectric material that is heat-resistant and transmits an electromagnetic wave (high frequency power), for example, quartz.

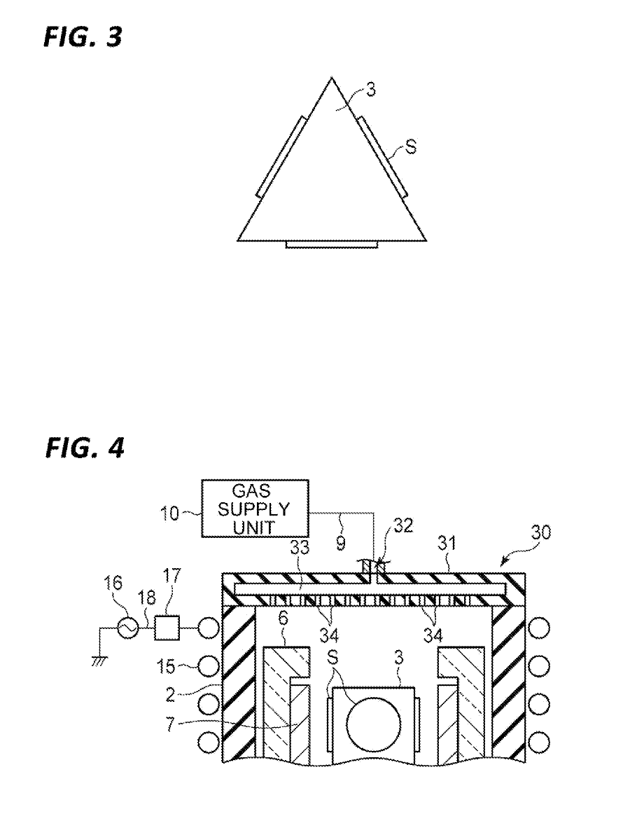

The processing container 2 is configured such that a susceptor 3 as a substrate holding member configured to hold a plurality of substrates S may be introduced into the processing container 2 from the bottom side of the processing container 2. The susceptor 3 is a barrel type formed in a polygonal column shape extending vertically in the processing container 2 and is made of graphite. In addition, a plurality of substrates S are held on each side surface of the susceptor 3. As for the shape of the susceptor 3, a hexagonal column as illustrated in FIG. 2 and a triangular column as illustrated in FIG. 3 are exemplified. Of course, other polygonal columns may be employed.

The susceptor 3 is configured to be rotated in the direction indicated by an arrow by a rotation mechanism 4 mounted below the susceptor 3. The rotation mechanism 4 is supported by a closure 5, and the closure 5, the rotation mechanism 4, and the susceptor 3 are adapted to be integrally lifted by a lifting mechanism (not illustrated). As such, the susceptor 3 is loaded or unloaded. In a state where the susceptor 3 is loaded in the processing container 2, the closure 5 closes the opening at the bottom end of the processing container 2, and the closure 5 and the bottom portion of the processing container 2 are sealed by a seal ring (not illustrated). The closure 5 is made of a heat-resistant material such as quartz.

Inside the processing container 2, a cylindrical heat insulation material 6 made of, for example, high-purity carbon is arranged along the inner wall of the processing container 2. Inside the heat insulation material 6, a cylindrical induction heating element 7 is installed to enclose the loaded susceptor 3. As described below, the induction heating element 7 is configured to generate heat when an induction current flows in the induction heating element. The induction heating element 7 is made of a conductive material having a high radiation rate, for example, graphite.

A gas inlet port 8 configured to introduce a processing gas is formed through a ceiling wall 2a of the processing container 2, a gas supply pipe 9 is connected to the gas inlet port 8, and a gas supply unit 10 is connected to the gas supply pipe 9. In addition, one or plural processing gases are supplied to the inside of the processing container 2 from the gas supply unit 10 and through the gas supply pipe 9 and the gas inlet port 8 with the flow rates of the processing gases being controlled by a flow controller (not illustrated).

Through the bottom portion of the processing container 2, an exhaust port 11 is formed and an exhaust pipe 12 is connected to the exhaust port 11. An exhaust device 14 including an automatic pressure control (APC) valve 13 and a vacuum pump is interposed on the way of the exhaust pipe 12 and the inside of the processing container 2 may be controlled to a prescribed vacuum degree by exhausting the inside of the processing container 2 while adjusting the opening degree of the automatic pressure control valve 13 by the exhaust device 14.

Outside the processing container 2, an induction heating coil 15 is installed. The induction heating coil 15 is formed by winding a metallic pipe in a helical shape around the outer circumference of the processing container 2 in the vertical direction and the winding region in the vertical direction is wider than the substrate mounting region. As for the metallic pipe that forms the induction heating coil 15, copper may be properly used. The induction heating coil 15 is configured to be supplied with a high frequency power from a high frequency power supply 16 through a feed line. On the way of the feed line 18, a matching circuit 17 is provided so as to perform an impedance matching.

When a high frequency power is applied to the induction heating coil 15, a high frequency wave is radiated from the induction heating coil 15. The high frequency wave transmits through the wall of the processing container 2 and arrives at the inside of the processing container 2 so that an induction magnetic field is formed. In addition, an induction current generated by the induction magnetic field flows to the induction heating element 7 so that the induction heating element 7 generates heat, and the substrates S are heated by the radiation heat thereof. The frequency of the high frequency wave of the frequency power supply 16 may be set to be in a range of, for example, 17 kHz or higher.

When the induction heating element 7 is inductively heated, the induction current is consumed. Thus, the amount of the induction current arriving at the substrates S through the induction heating element 7 is reduced and the flow of the induction current to the substrates S is blocked by the induction heating element 7. The magnitude of the induction current transmitting through the induction heating element 7 is varied depending on the thickness of the induction heating element 7, the frequency of the high frequency power, and the distance between the induction heating coil 15 and the substrates S. Thus, the present exemplary embodiment adjusts at least one of them in order to block the flow of the induction current to the substrates S. For example, when the frequency of the high frequency power and the distance between the induction heating coil 15 and the substrates S are fixed, only the thickness of the induction heating element 7 is adjusted. When only the distance between the induction heating coil 15 and the substrates S is fixed, the frequency of the high frequency power and the thickness of the induction heating element 7 are adjusted. When the thickness of the induction heating element and the distance between the induction heating coil 15 and the substrates S are fixed, only the frequency of the high frequency power is adjusted. At this time, it is desirable to adjust the conditions such that the induction current does not flow to the substrates S. However, the induction current flowing to the substrates S may be allowed when the induction current has a very small value which does not affect the uniformity in processing.

Respective constituent elements of the heat treatment device 1 are controlled by a control unit (computer) 20. The control unit 20 includes a controller which is provided with a microprocessor, a user interface including, for example, a keyboard where an operator performs, for example, an input operation of a command for managing the heat treatment device 1 or a display that visualizes and displays an operation situation of the heat treatment device 1, and a storage unit which stores a control program for implementing various processings executed by the heat treatment device 1 by the control of the controller or a processing recipe for executing a prescribed processing in the heat treatment device 1 according to a processing condition. The processing recipe or the like is stored in a storage medium and is read from the storage medium to the storage unit to be executed. The storage medium may be a hard disc or a semiconductor memory. Alternatively, the storage medium may be a portable medium such as, for example, a CD-ROM, DVD, or a flash memory. The recipe may be read from the storage unit to be executed in the controller, for example, by an instruction from the user interface as needed so that a desired processing by the heat treatment device 1 may be performed under the control of the controller.

Next, descriptions will be made on the heat treatment performed using the heat treatment device 1.

In a state where the susceptor 3 is lowered, a plurality of substrates S are mounted on the susceptor 3, and the susceptor mounted with the substrates S are raised by the lifting mechanism to be loaded in the processing container 2. At this time, the closure 5 is raised to block the opening at the bottom end of the processing container 2, the closure 5 and the bottom portion of the processing container 2 are sealed by a seal ring (not illustrated) so that the inside of the processing container 2 is in the sealed state.

At this time, the high frequency power supply 16 is turned ON to apply a high frequency power to the induction heating coil 15 so that the substrates S on the susceptor are heated. Specifically, when the high frequency power is applied to the induction heating coil 15, an induction magnetic field is formed within the processing container 2, and an induction current by the induction magnetic field flows to the induction heating element 7 so that the induction heating element 7 generates heat. In addition, the substrates S on the susceptor 3 are heated by the radiation heat of the induction heating element 7.

As the substrates S are heated as described above, a processing gas required for heat treatment is supplied to the inside of the processing container 2 from the gas supply unit 10 while controlling the flow rate of the processing gas and is exhausted from the exhaust port 11 by the exhaust device 14 while controlling the automatic pressure control (APC) valve 13 to maintain the inside of the processing container 2 at a prescribed pressure and the susceptor 3 is rotated by the rotation mechanism 4. At this time, the temperature of the substrates S is measured by a thermocouple (not illustrated) provided within the processing container 2, and the power of the high frequency power is controlled based on the temperature. As a result, the heat treatment is performed on the substrates S by a prescribed processing gas while controlling the temperature of the substrates S at a prescribed process temperature.

The heat treatment may be, for example, a film forming processing that forms a prescribed film by causing a reaction of processing gases on a surface of a substrate or an oxidation processing that oxidizes a surface of a substrate. In particular, the heat treatment is suitable for a heat treatment which requires heating in excess of 1000° C. which is difficult to apply by resistance heating or lamp heating may not be applied and a film forming of a compound film such as a silicon carbide (SiC) film or a gallium nitride (GaN) film may be a representative example of such a heat treatment. In the case of SiC, a single crystal SiC by epitaxial growth or a polycrystalline SiC by CVD, using Si or SiC as a substrate S. In addition, in the case of GaN, a single crystal GaN may be formed by epitaxial growth or a polycrystalline GaN may be formed by CVD, using sapphire as a substrate S.

When forming a SiC film, as for processing gases, a silane-based gas such as, for example, SiH₄, as a Si source, a hydrocarbon gas such as, for example, C₃H₈, as a C source, and H₂ gas as a reducing gas may be used.

In addition, when forming a GaN film, for example, an organic gallium compound such as for example, trimethylgallium (TGMa) as a Ga source, and NH₃ as an N source and a reducing gas may be used.

Conventionally, when heating a substrate S by induction heating, an induction current is applied to a susceptor 3 so as to heat the substrate S by the heat. However, in such a case, since the induction current also flows to the substrate S, it is difficult to perform a uniform processing. In particular, when forming a compound film, for example, ununiformity of the film thickness or the film composition may be caused.

Therefore, in the present exemplary embodiment, an induction heating element 7 is installed between the induction heating coil 15 and the substrates S, an induction current is applied to the induction heating element 7 so as to generate heat, and the substrates S are heated by the radiation heat of the induction heating element 7 at that time. Thus, the induction current is consumed in the induction heating element 7 so that the induction current that flows to the substrates S through the induction heating element 7 may be remarkably reduced and the flow of the induction current to the substrates S may be blocked by the induction heating element 7. The magnitude of the induction current that penetrates the induction heating element 7 without being consumed is variable depending on the thickness of the induction heating element 7. Therefore, the frequency of the high frequency power, and the distance between the induction heating coil 15 and the substrate S, in the present exemplary embodiment, at least one of them is adjusted such that the induction current arriving at the substrate S is substantially blocked. At this time, it is desirable to define a condition such that the induction current does not flow to the substrates S. However, a minute current that does not affect processing ununiformity is allowable.

As described above, in the present exemplary embodiment, the induction current generating inside the processing container 2 is made to flow little to the substrates S. Thus, a uniform heat treatment may be achieved without causing deterioration of uniformity in processing.

When the heat treatment is a film forming processing, as illustrated in FIG. 4, a shower head 30 may be provided instead of the ceiling wall 2a in view of supplying the processing gas to the substrates S more uniformly. The shower head 30 includes a body 31, a gas inlet port 32 provided on the top of the body 31 and connected with the gas supply pipe 9, a gas diffusion space 33 formed horizontally inside the body 31, and a plurality of gas ejecting holes 34 formed through a bottom surface of the body 31 from the gas diffusion space 33. In addition, the processing gas is ejected into the inside of the processing container 2 from the plurality of gas ejecting holes 34 in a shower form. Accordingly, the processing gas is uniformly supplied to the inside of the processing container 2.

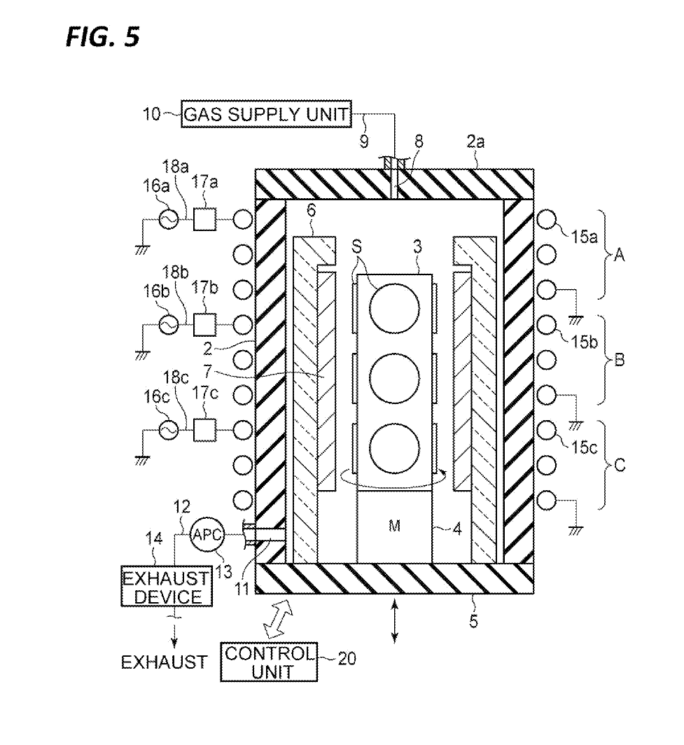

In addition, in order to improve the temperature uniformity in the height direction within the processing container 2, as illustrated in FIG. 5, the induction heating coil may be divided into a plurality of zones such that the high frequency power may be individually controlled for each of the zones. In the example of FIG. 5, the heating coil is divided into three zones A, B, C in the height direction in which, in the zone A, an induction heating coil 15a is wound to be supplied with a high frequency power from a high frequency power supply 16a, in the zone B, an induction heating coil 15b is wound to be supplied with a high frequency power from a high frequency power supply 16b, and in the zone C, an induction heating coil 15c is wound to be supplied with a high frequency power from the high frequency power supply 16c such that the high frequency power of each zone may be controlled. The number of the zones is not limited to three and may be two or may be four or more. Reference numerals 17a, 17b, 17c indicate matching circuits of the zones, respectively, and reference numerals 18a, 18b, 18c indicate the power feeding lines of the respective zones.

As described above, according to the present exemplary embodiment, an induction heating element is provided between an induction heating coil and a susceptor to surround the susceptor which is a substrate holding member within a processing container, the induction heating element is heated by an induction current formed by an induction magnetic field within the processing container, a substrate held by the susceptor is heated by a radiation heat of the susceptor, and the flow of the induction current to the substrate is blocked by the induction heating element. Accordingly, a heat treatment may be performed uniformly while excluding the influence of the induction current on the substrate.

### Second Exemplary Embodiment

Next, descriptions will be made on a second exemplary embodiment of the present disclosure.

The present exemplary embodiment represents a heat treatment device suitable for film forming a compound film.

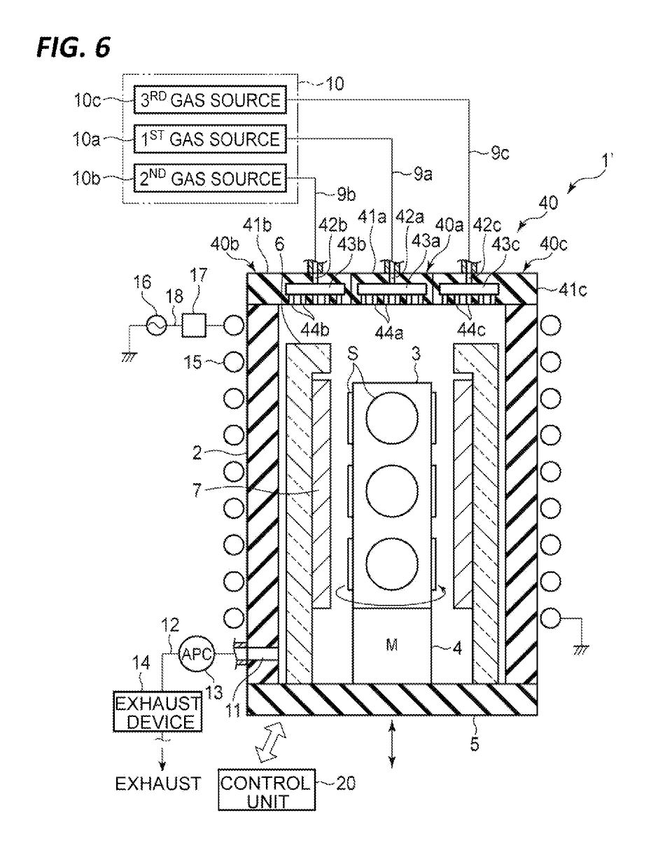

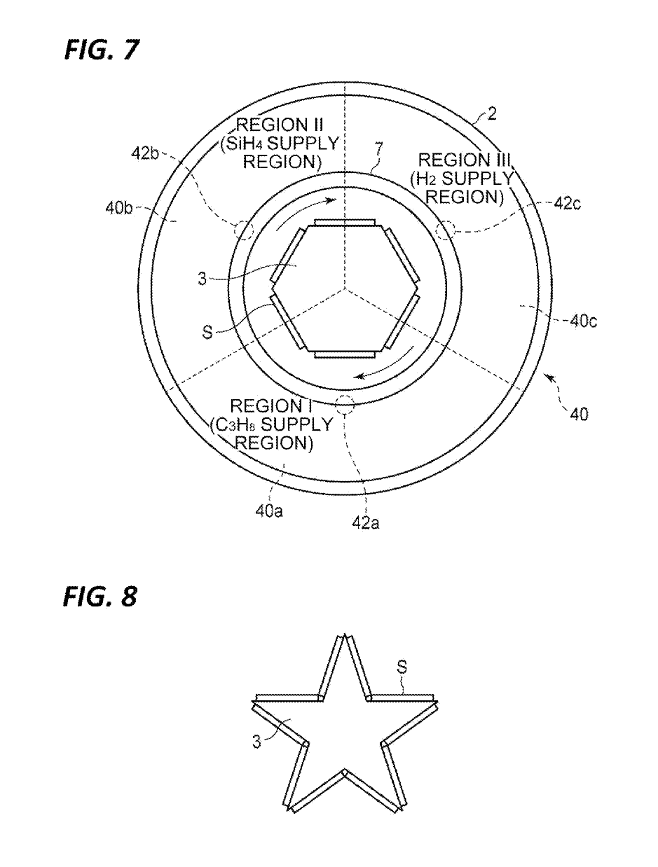

FIG. 6 is a cross-sectional view illustrating a heat treatment device according to the second exemplary embodiment, and FIG. 7 is a schematic view illustrating a concept when forming a SiC film using the heat treatment device according to the second exemplary embodiment.

In FIGS. 6 and 7, the elements similar to those of the first exemplary embodiment are indicated by the similar reference numerals and descriptions thereof will be omitted. As illustrated in the drawings, in the heat treatment device 1′, the ceiling wall of the processing container 2 is configured by a shower head 40 formed in a divided type disc shape. In the present exemplary embodiment, the shower head 40 is divided into three, i.e. a first shower head 40a, a second shower head 40b, a third shower head 40c (see, e.g., FIG. 7). The first shower head 40a includes a body 41a, a gas inlet port 42a provided on the top of the body 41a, a gas diffusion space 43a formed horizontally inside the body 41a, and a plurality of gas ejecting holes 44a extending through the bottom surface of the body 41a from the gas diffusion space 43a. The second shower head 40b includes a body 41b, a gas inlet port 42b provided on the top of the body 41b, a gas diffusion space 43b formed horizontally inside the body 41b, and a plurality of gas ejecting holes 44b extending through the bottom surface of the body 41b from the gas diffusion space 43b. The third shower head 40c includes a body 41c, a gas inlet port 42c provided on the top of the body 41c, a gas diffusion space 43c formed horizontally inside the body 41c, and a plurality of gas ejecting holes 44c extending through the bottom surface of the body 41c from the gas diffusion space 43c. Gas supply pipes 9a, 9b, 9c are connected to the gas inlet ports 42a, 42b, 42c, the gas supply pipes 9a, 9b, 9c are connected to a first source gas source 10a, a second gas source 10b, and a third gas source 10c of a gas supply unit 10, respectively. In addition, the first shower head 40a is supplied with a first gas from the first gas source 10a, the second shower head 40b is supplied with a second gas from the second gas source 10b, and the third shower head 40c is supplied with a third gas from the third gas source 10c such that the first gas, the second gas, and the third gas are ejected from the first shower head 40a, the second shower head 40b, and the third shower head 40c, respectively. Although not illustrated, each of the gas supply pipes 9a, 9b, 9c is equipped with a valve and a flow controller such that the supply of the first gas, second gas, and third gas may be performed or stopped and the flow rates thereof may be controlled.

In the heat treatment device of the second exemplary embodiment configured as described above, as in the first exemplary embodiment, a plurality of substrates S are mounted on the susceptor 3 in the state where the susceptor 3 is lowered, the susceptor 3 mounted with the substrates S is raised by a lifting mechanism so as to load the substrates S in the processing container 2, and the lower end opening of the processing container 2 is closed by the closure 5 so that the inside of the processing container 2 is sealed.

At this time, the high frequency power supply 16 is turned ON so as to apply a high frequency power to the induction heating coil 15 so that an induction magnetic field is formed inside the processing container 2 and an induction current flows to the induction heating element 7 by the induction magnetic field so as to cause the induction heating element 7 to generate heat. As a result, the substrates S on the susceptor 3 are heated by the radiation heat of the induction heating element 7.

While heating the substrates S as described above, the first gas, the second gas, and the third gas are supplied from the first gas source 10a, the second gas source 10b, and the third gas source 10c of the gas supply unit 10, to the first shower head 40a, the second shower head 40b, and the third shower head 40c, respectively, and the first gas, the second gas, and the third gas are ejected to the inside of the processing container 2 from the shower heads, respectively. At this time, the first gas, the second gas, and the third gas are supplied while controlling the flow rates thereof and exhausted from the exhaust port 11 by the exhaust device 14 while controlling the automatic pressure control valve (APC) 13 so that the inside of the processing container 2 may be maintained at a prescribed pressure. The temperature of the substrates S is measured by a thermocouple provided within the processing container 2, and the power of the high frequency power is controlled based on the temperature so that the temperature of the substrates S may be controlled to a process temperature.

At this time, a region corresponding to the first shower head 40a within the processing container 2 (region I in FIG. 7) becomes an atmosphere of the first gas, a region corresponding to the first shower head 40b within the processing container 2 (region II in FIG. 7) becomes an atmosphere of the second gas, and a region corresponding to the third shower head 40c within the processing container 2 (region III in FIG. 7) becomes an atmosphere of the third gas. At this state, when the susceptor 3 is rotated by the rotation mechanism 4, the substrates S pass respective regions so that the first gas, the second gas, and third gas are repeatedly adsorbed, thereby forming a prescribed compound film in a form of atomic layer deposition (ALD).

As a typical specific example, C₃H₈ gas is used as a C source, SiH₄ gas is used as a Si source, and H₂ gas is used as a reducing gas. When the C₃H₈ gas is ejected from the first shower head 40a as the first gas, the SiH₄ gas is ejected from the second shower head 40b as the second gas, and the H₂ gas is ejected from the third shower head 40c as the third gas, region I within the processing container 2 is formed with a C₃H₈ gas atmosphere as the C₃H₈ gas supply region, region II is formed with a SiH₄ gas atmosphere as the SiH₄ gas supply region, and region III is formed with a H₂ gas atmosphere as the H₂ gas supply region. When the susceptor 3 is rotated so as to cause the substrates S to sequentially pass these regions, a SiC film may be formed by an ALD method (see FIG. 7).

When the ALD method is used, the reactivity of each gas is improved such that a high pure compound film may be formed at a lower temperature.

At this time, the number of gas instruction portions and the number of the regions are not limited to three and are determined by the number of processing gases for forming the compound film.

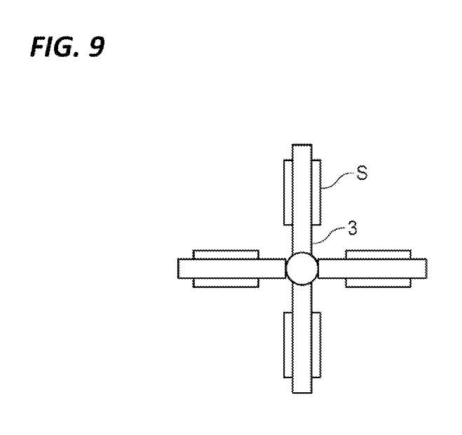

Further, the present disclosure is not limited to the above described exemplary bodies and may be various modified. For example, although it is illustrated that the susceptor 3 is a barrel type formed in a polygonal column shape, various susceptors, for example, a susceptor with a star-shape cross section as illustrated in FIG. 8 and a susceptor with a cross-shape cross section as illustrated in FIG. 9, may be used.

In addition, although a film forming processing, in particular, a compound film forming processing is suitable as the heat treatment, any processing may be included in the heat treatment of the present invention if the processing heats a substrate while supplying a processing gas. For example, an oxidation processing, an annealing processing, and a diffusion processing may be included in the heat treatment of the present invention.

In addition, as for the substrates, various substrates such as semiconductor substrates, sapphire substrates, ZnO substrates, and glass substrates may be used without any specific limitation.

In addition, although graphite has been exemplified as a material for the induction heating element in the exemplary embodiments described above, a conductive ceramics such as SiC may be used without being limited thereto.

### [Description of Reference Numerals]

1: heat treatment device

2: processing container

3: susceptor

4: rotation mechanism

5: closure

7: induction heating element

8, 32, 42a, 42b, 42c: gas inlet port

9, 9a, 9b, 9c: gas supply pipe

10: gas supply unit

11: exhaust port

12: exhaust pipe

14: exhaust device

15: induction heating coil

16: high frequency power supply

20: control unit

30, 40: shower head

40a: first shower head

40b: second shower head

40c: third shower head

S: substrate

What is claimed is:

1. A heat treatment device comprising:
a processing container configured to accommodate a plurality of substrates to be subjected to a heat treatment;
a substrate holding member configured to hold the plurality of substrates inside the processing container;
an induction heating coil configured to form an induction magnetic field inside the processing so as to perform induction heating;
a high frequency power supply configured to apply a high frequency power to the induction heating coil;
a gas supply mechanism configured to supply one or more processing gases to the inside of the processing container;
an exhaust mechanism configured to exhaust the inside of the processing container; and
an induction heating element provided between the induction heating coil and the substrate holding member so as to enclose the substrate holding member inside the processing container, the induction heating element being heated by an induction electric current formed by the induction magnetic field and the plurality of substrates held by the substrate holding element being heated by radiation heat from the induction heating element,
wherein the flow of the induction electric current to the plurality of substrates is blocked by the induction heating element.

2. The heat treatment device of claim 1, wherein at least one of the thickness of the induction heating element, the frequency of the high frequency power and the distance between the induction heating coil and the plurality of substrates is adjusted in such a manner that the flow of the induction current to the plurality of substrates may be blocked.

3. The heat treatment device of claim 1, wherein the processing container is made of a dielectric material and the induction heating coil is wound on an outer circumference of the processing container.

4. The heat treatment device of claim 1, wherein the substrate holding member forms a polygonal column extending vertically in the processing container, and the plurality of substrates are held on side surfaces of the substrate holding member.

5. The heat treatment device of claim 1, wherein the induction heating element is made of graphite.

6. The heat treatment device of claim 1, wherein the gas supply mechanism includes a shower head configured to introduce the processing gases into the processing container in a form of shower.

7. The heat treatment device of claim 1, further comprising a rotation mechanism configured to rotate the substrate holding member.

8. The heat treatment device of claim 1, the heat treatment is a film-forming processing that forms a prescribed film by reacting the processing gases on the plurality of substrates.

9. The heat treatment device of claim 8, wherein the heat treatment forms a silicon carbide (SiC) film or a gallium nitride (GaN) film.

10. The heat treatment device of claim 1, wherein the heat treatment forms a compound film using a plurality of processing gases and the heat treatment device further includes a rotation mechanism configured to rotate the substrate holding member, and
wherein the gas supply mechanism supplies each of the plurality of processing gases to one of different regions in the processing container and the substrate holding member is rotated by the rotation mechanism so that the plurality of substrates may sequentially pass through each of the regions, thereby causing the plurality of processing gases to be sequentially adsorbed onto the plurality of substrates.

11. The heat treatment device of claim 10, wherein the gas supply mechanism includes a plurality of shower heads that are configured to introduce the plurality of processing gases to the different regions in the processing container, respectively.

12. The heat treatment device of claim 10, wherein the compound film is a SiC film, and a Si source gas, a C source gas and a reducing gas are used as the plurality of gases.
